(19) United States
(12) Patent Application Publication
(10) Pub. No.: US 2007/0057266 A1
(43) Pub. Date: Mar. 15, 2007

(54) Light emitting diode with diffraction lattice

(76) Inventors: Pei-Jih Wang, Dashi (TW); Pan-Tzu Chang, Dashi (TW); Wen-Chieh Huang, Dashi (TW); James Wang, Dashi (TW); Yury Georgievich Shreter, St Petersburg (RU); Yury Toomasovich Rebane, St Petersburg (RU); Ruslan Ivanovich Gorbunov, St Petersburg (RU)

Correspondence Address: ROSENBERG, KLEIN & LEE, 3458 ELLICOTT CENTER DRIVE-SUITE 101, ELLICOTT CITY, MD, 21043, US

(21) Appl. No.: 11/595,910

(22) Filed: Nov. 13, 2006

Related U.S. Application Data
(62) Division of application No. 10/928,094, filed on Aug. 30, 2004.

(51) Int. Cl. H01L 33/00

(52) U.S. Cl. 257/89; 257/98; 257/E33.073

(57) ABSTRACT

A method of fabricating light emitting diodes (LED) with a colour purifying diffraction lattice (CPDL) is suggested, the essence of the invention is in the use of the coherent scattering of the light by the CPDL for colour purifying of the light emitted by the LED and enhancement its extraction efficiency, the CPDL is a hexagonal two-dimensional periodical pattern on the surface of the LED structure or an internal interface resulting in the periodical variation in the refractive index with the period d The period of CPDL satisfies the equation d=m.lamda./n, where m is a positive integer number, .lamda. is the wavelength of the light generated by LED, and n is the refraction index of LED structure. The height of the hexagonal islands forming CPDL is h=.lamda.(2l+1)/2n, l is a positive integer number or zero. Use of CPDL allows to convert the laterally propagating light into the vertically propagating and simultaneously filter its spectrum.

### RELATED APPLICATIONS

This application is a Divisional patent application of co-pending application Ser. No. 10/928,094, filed on 30 Aug. 2004.

### BACKGROUND OF THE INVENTION

1. Field of the Invention

The present invention relates to a method for fabricating a light emitting diodes (LED). More particularly, the invention relates to a method of fabricating LED with pure colour and enhanced light extraction efficiency.

2. Description of the Prior Art

Generally light extraction efficiency of LEDs is limited by high refractive index of the LED chip material which prevents the light escape from the LED chip when its incident angles is higher than the angle of total internal reflection FIG. 1. This results in low light extraction efficiency of ordinary LEDs which is typically less than 10%.

To enhance the light extraction efficiency various methods had been proposed.

These are pyramidal-like shaped LED chip taught by M. R. Krames et. al. Applied Physics Letters, 75, pp. 2365, (1999), a random surface texture taught by Schnitzer, et al in Applied Physics Letters 63, 2174 (1993), an ordered interface texturing taught by M. R Krames et al. U.S. Pat. No. 5,779,924.

All above methods allow to suppress the light reflection at the surface of the LED chip and change the angular bandwidth of light which may transmit power into the ambient, but they are not very sensitive to the emitted wavelength. This does not allow a precise fitting the light extraction properties to a given wavelength and filtering of the light spectrum emitted by the LED.

The present invention allows to overcome this disadvantage by the using of special hexagonal diffraction lattice with precisely determined parameters that allow to convert the laterally propagating light into the vertically propagating light and simultaneously filter the light spectrum emitted by the LED.

### SUMMARY OF THE INVENTION

This invention states LED with a colour purifying diffraction lattice (CPDL).

The essence of the invention is in the use of the coherent scattering of the light by the CPDL for colour purifying of the light emitted by the LED and enhancement its extraction efficiency.

Use of CPDL allows to convert the laterally propagating light into the vertically propagating light with high efficiency and, simultaneously filter the light spectrum emitted by the LED.

The LED spectrum filtering by the diffraction lattice allows to purify the colour of the light emitted by LED. Also, the LED spectrum filtering allows to reduce the difference in the wavelengths of the LED chips produced from different part of the wafer and from different wafers.

A method of obtaining the two-dimensional CPDL as a self organized ordered porous pattern of Al.sub.2O.sub.3 amorphous films developed on Al film by an anodic oxidation. The period and depth of the pores in Al.sub.2O.sub.3 films are controlled by applied voltage, content of electrolyte and time of oxidation.

### BRIEF DESCRIPTION OF THE DRAWINGS

In the accompanying drawings:

FIG. 1. is a diagram exhibiting the conventional LED without CPDL. Light beam with incident angle higher than the angle of total internal reflection is captured in the chip.

FIG. 2. is a principal scheme of the LED chip with CPDL on top surface. CPDL converts the laterally propagating light into the vertically propagating light.

FIG. 3. is a principal scheme of the LED chip with CPDL on interface between LED structure and substrate. CPDL converts the laterally propagating light into the vertically propagating light.

FIG. 4. shows first variant of CPDL, d is the period of CPDL, s is the length of the side of hexagon islands forming CPDL.

FIG. 5. shows second variant of CPDL, d is the period of CPDL, s is the length of the side of hexagon islands forming CPDL.

FIG. 6. shows third variant of CPDL, d is the period of CPDL, r is the radius of the cylindrical holes forming CPDL.

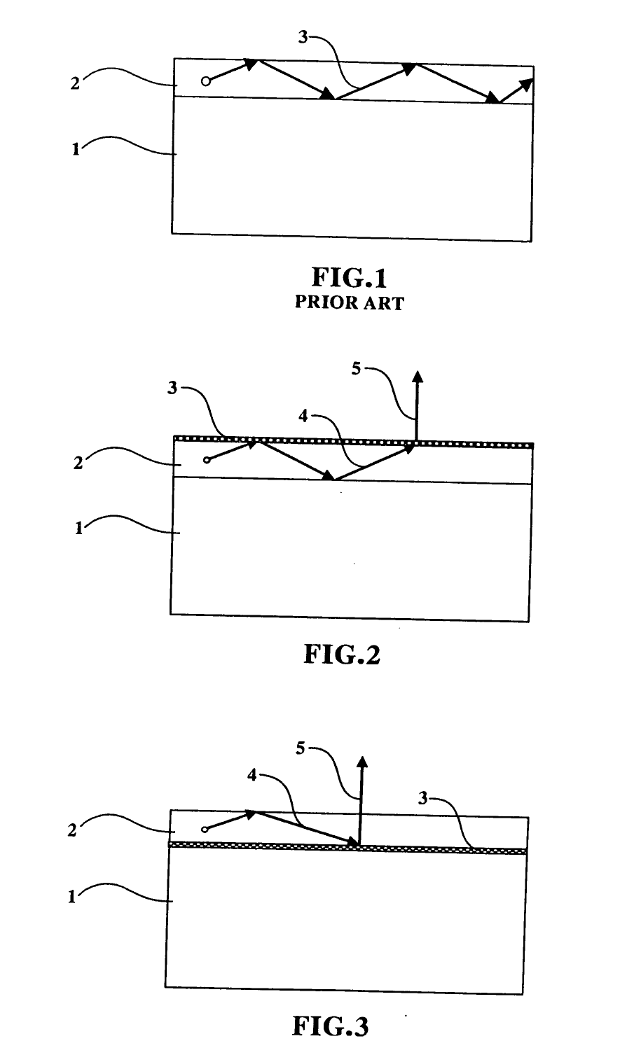

### DETAILED DESCRIPTION OF THE PREFERED EMBODIMENTS

The invention will be more fully understood by reference to the following examples:

### EXAMPLE 1

The principal scheme of the LED embodied in Example 1 is shown in FIG. 2. It has a sapphire (Al.sub.2O.sub.3) substrate 1 upon which a gallium-nitride-based LED structure 2 is grown.

On the gallium-nitride-based LED structure a two-dimensional CPDL 3 is formed by dry surface etching. The light scattering by CPDL convert the laterally propagating light 4 into the vertically propagating light 5 and, thus, enhance the light extraction efficiency.

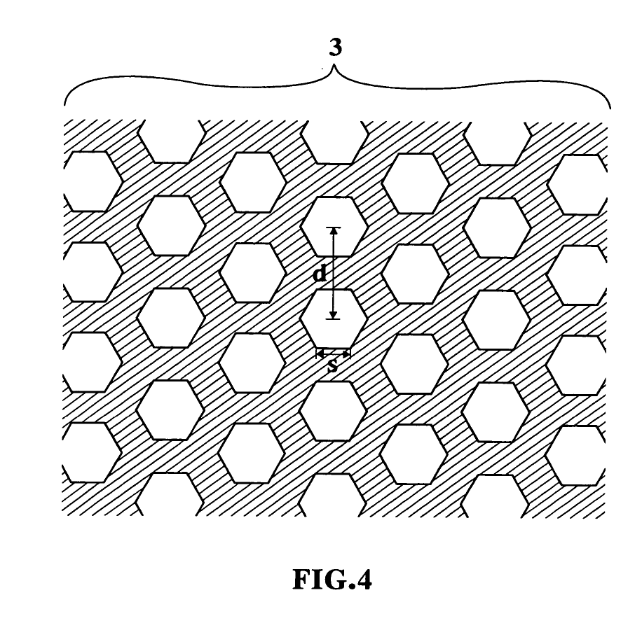

The CPDL structure is shown in FIG. 4.

The period d of the CPDL should satisfy the equation d=m.lamda./n, where m=1, 2, 3 . . . and .lamda. is the wavelength of the light generated by LED, and n is the refraction index of GaN. To make the scattering with m=1, 2, 3 . . . most effective the zero order of diffraction with m=0 should be suppressed. This happens when height of the hexagonal islands forming CPDL is h=.lamda.(2l+1)/2n, l=0, 1, 2, 3 . . ., and total areas of islands and trenches in CPDL are equal. To make these areas equal the side s hexagon islands should satisfy the equation s=d/2 2. Thus, for LED with .lamda.=0.42 .mu.m the parameters of the CPDL with m=1, l=0 are d=0.17 mu.m, h=0.085 mu.m, s=0.06 .mu.m. Use of CPDL allows to convert the laterally propagating light into the vertically propagating light with high efficiency and, simultaneously filter of the light spectrum emitted by the LED.

The LED spectrum filtering by the diffraction lattice allows to purify the colour of the light emitted by LED. Also, the LED spectrum filtering allows to reduce the difference in the wavelengths of the LED chips produced from different part of the wafer and from different wafers.

### EXAMPLE 2

The principal scheme of the LED embodied in Example 2 is shown in FIG. 3. It has a sapphire (Al.sub.2O.sub.3) substrate 1 on which a two-dimensional CPDL 3 is formed by surface etching. On the CPDL a gallium-nitride-based LED structure 2 is grown.

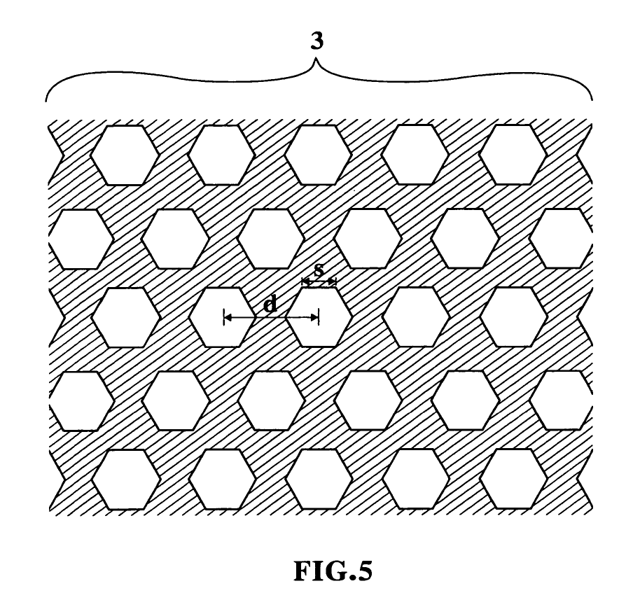

The CPDL structure is shown in FIG. 5.

The light scattering by CPDL convert the laterally propagating light 4 into the vertically propagating light 5 and, thus, enhance the light extraction efficiency.

The period d of the CPDL should satisfy the equation d=m.lamda./n, where m=1, 2, 3 . . . and .lamda. is the wavelength of the light generated by LED, and n is the refraction index of GaN. To make the scattering with m=1, 2, 3 . . . most effective the zero order of diffraction with m=0 should be suppressed. This happens when heights of the hexagonal islands forming CPDL is h=.lamda.(2l+1)2n, l=0, 1, 2, 3 . . , and total areas of islands and trenches in CPDL are equal. To make these areas equal the side s hexagon islands should satisfy the equation s=d/2 2.

For LED with .lamda.=0.5 .mu.m the parameters of the CPDL with m=2, l=0 are d=0.4 mu.m, h=0.1 mu.m, s=0.14 .mu.m.

Use of CPDL allows to convert the laterally propagating light into the vertically propagating light with high efficiency and, simultaneously filter of the light spectrum emitted by the LED.

The LED spectrum filtering by the diffraction lattice allows to purify the colour of the light emitted by LED. Also, the LED spectrum filtering allows to reduce the difference in the wavelengths of the LED chips produced from different part of the wafer and from different wafers.

### EXAMPLE 3

The principal scheme of the LED embodied in Example 3 is shown in FIG. 2. It has a sapphire (Al.sub.2O.sub.3) substrate 1 upon which a gallium-nitride-based LED structure 2 is grown.

On the gallium-nitride-based LED structure a two-dimensional Al.sub.2O.sub.3 CPDL 3 is deposited.

The Al.sub.2O.sub.3 CPDL 3 is formed by an anodic oxidation of Al film.

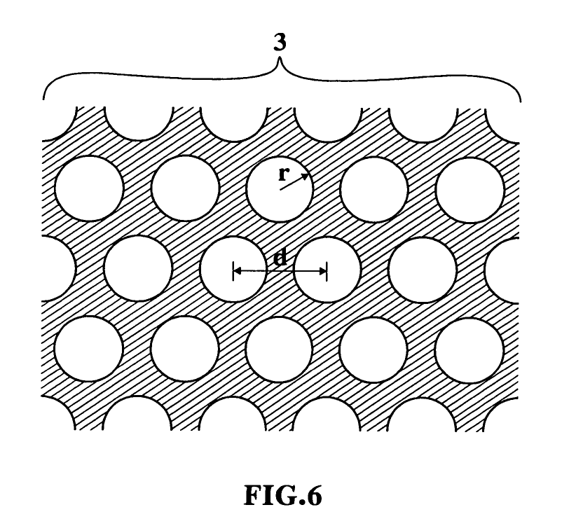

The CPDL structure is shown in FIG. 6.

The period d of the CPDL should satisfy the equation d=m.lamda./n, where m=1, 2, 3 . . . and .lamda. is the wavelength of the light generated by LED, and n is the refraction index of GaN. To make the scattering with m=1, 2, 3 . . . most effective the zero order of diffraction with m=0 should be suppressed. This happens when depths of the cylindrical holes forming CPDL is h=.lamda.(2l+1)/2n, l is a positive integer number or zero, and their radii r satisfy the equation r=d(3/4.pi.).sup. 1/2.

For LED with .lamda.=0.5 .mu.m the parameters of the CPDL with m=1, l=0 are d=0.21 mu.m, h=0.1 .mu.m, r=0.08 mu.m.

Use of CPDL allows to convert the laterally propagating light into the vertically propagating light with high efficiency and, simultaneously filter of the light spectrum emitted by the LED.

The LED spectrum filtering by the diffraction lattice allows to purify the colour of the light emitted by LED. Also, the LED spectrum filtering allows to reduce the difference in the wavelengths of the LED chips produced from different part of the wafer and from different wafers.

### EXAMPLE 4

The principal scheme of the LED embodied in Example 4 is shown in FIG. 2. It has a GaAs substrate 1 upon which a AlGaInP-based LED structure 2 is grown.

On the AlGaInP-based LED structure a two-dimensional Al.sub.2O.sub.3 CPDL 3 is deposited.

The Al.sub.2O.sub.3 CPDL 3 is formed by an anodic oxidation of Al film.

The CPDL structure is shown in FIG. 6.

The period d of the CPDL should satisfy the equation d=m.lamda./n, where m=1, 2, 3 . . . and .lamda. is the wavelength of the light generated by LED, and n is the refraction index of AlGaInP. To make the scattering with m=1, 2, 3 . . . most effective the zero order of diffraction with m=0 should be suppressed. This happens when depths of the cylindrical holes forming CPDL is h=.lamda.(2l+1)/2n, and l is a positive integer number or zero, and their radii r satisfy the equation r=d(3/4.pi.).sup. 1/2.

For LED with .lamda.=0.6 .mu.m the parameters of the CPDL with m=1 are d=0.18 .mu.m, h=0.09 m (1=10), r=0.066 .mu.m.

Use of CPDL allows to convert the laterally propagating light into the vertically propagating light with high efficiency and, simultaneously filter of the light spectrum emitted by the LED.

The LED spectrum filtering by the diffraction lattice allows to purify the colour of the light emitted by LED. Also, the LED spectrum filtering allows to reduce the difference in the wavelengths of the LED chips produced from different part of the wafer and from different wafers.

Many changes and modifications in the above-described embodiments of the invention can, of course, be carried out without departing from the scope thereof. Accordingly, to promote the progress in science and the useful arts, the invention is disclosed and is intended to be limited only by the scope of the appended claims.

1. A light emitting diode comprising: a substrate; a two-dimensional colour purifing diffraction lattice (CPDL) formed on the surface of said substrate; and a LED structure formed on the surface of said CPDL.

2. A light emitting diode as recited in claim 1, wherein said substrate is selected from a group consisting of sapphire (Al.sub.2O.sub.3) and GaAs.

3. A light emitting diode as recited in claim 1, wherein said LED structure is selected from a group consisting of GaN based and AlGaInP.

4. A light emitting diode as recited in claim 1, wherein said two-dimensional CPDL formed by dry etching on the surface of substrate upon which a LED structure is grown, the period d of the CPDL satisfy the equation d=m.lamda./n, where m is a positive integer number, .lamda. is the wavelength of the light generated by LED, and n is the refraction index of LED structure.

5. A light emitting diode as recited in claim 1, wherein said two-dimensional CPDL formed by an anodic oxidation of Al film formed on or attached to the surface of substrate upon which a LED structure is grown, the period d of the CPDL satisfy the equation d=m.lamda./n, where m is a positive integer number, .lamda. is the wavelength of the light generated by LED, and n is the refraction index of LED structure.

6. A light emitting diode as recited in claim 1, wherein said two-dimensional CPDL formed by dry etching of substrate upon which a LED structure is grown and having patterns shown in FIG. 4, the period d of the CPDL satisfy the equation d=m.lamda./n, where m is a positive integer number, .lamda. is the wavelength of the light generated by LED, and n is the refraction index of LED structure, the height of the hexagonal islands forming CPDL is h=.lamda./2n, and their side s satisfy the equation s=d/2 2.

7. A light emitting diode as recited in claim 1, wherein said two-dimensional CPDL formed by dry etching of substrate upon which a LED structure is grown and having patterns shown in FIG. 5, the period the period d of the CPDL satisfy the equation d=m.lamda./n, where m is a positive integer number, A is the wavelength of the light generated by LED, and n is the refraction index of LED structure, the height of the hexagonal islands forming CPDL is h=.lamda.(2l+1)/2n, l is a positive integer number or zero, and their side s satisfy the equation s=d/2 2.

8. A light emitting deode as recited in claim 1, wherein said two-dimensional CPDL formed by an anodic oxidation of Al film formed or attached to the surface of substrate upon which a LED structure is grown and having patterns shown in FIG. 6, the period d of the CPDL satisfy the equation d=m.lamda./n, where m is a positive integer number, .lamda. is the wavelength of the light generated by LED, and n is the refraction index of LED structure, the depth of the cylindrical holes forming CPDL is h=.lamda.(2l+1)/2n, l is a positive integer number or zero, and their radius r satisfy the equation r=d(3/4.pi.).sup. 1/2.
